(19) United States
(12) Patent Application Publication
(10) Pub. No.: US 2024/0329704 A1
(43) Pub. Date: Oct. 3, 2024

(54) HEAT DISSIPATION DEVICE HAVING NOISE CANCELLING MODULE

(71) Applicant: TAIWAN MICROLOOPS CORP., New Taipei City (TW)

(72) Inventor: Chun-Hung LIN, New Taipei City (TW)

(21) Appl. No.: 18/207,126

(22) Filed: Jun. 7, 2023

(30) Foreign Application Priority Data
Mar. 31, 2023 (TW) 112112417

(51) Int. Cl. G06F 1/20; G10K 11/16; H05K 7/20

(52) U.S. Cl. CPC G06F 1/206; G10K 11/16; H05K 7/20154

(57) ABSTRACT

A heat dissipation device having a noise cancelling module includes: a seat body; a cover member correspondingly covering the seat body, and an accommodation chamber is formed between the seat body and the cover member, the cover member has an air inlet port and an air outlet port communicating with the accommodation chamber; a fan disposed in the accommodation chamber and arranged corresponding to the air inlet port, and having a plurality of blades; a heat dissipation fin set disposed in the accommodation chamber and arranged corresponding to the air outlet port; and a noise cancelling module generating a noise cancellation sound, the noise cancelling module is disposed on the cover member or the heat dissipation fin set to make the noise cancellation sound offset a noise generated when each of the blades rotates.

### BACKGROUND OF THE DISCLOSURE

### Technical Field

The present disclosure relates to a heat dissipation device, especially to a heat dissipation device having a noise cancelling module.

### Description of Related Art

With the enhanced performance of the graphic software and the display function, the display chip disposed on the graphics card and used for processing images is provided with a greater calculating capability, thus problems of heat generating and heat dissipating of a graphic processing unit (GPU) are required to be improved. Moreover, a central processing unit (CPU) disposed on a motherboard of a computer also has the aforesaid problems.

In the related-art heat dissipating deign applied on the display card, a water cooling method is used to dissipate heat, and an air cooling (or a gas cooling) method is also used to dissipate heat. A common method is to utilize a fan to blow away the heat generated by the heat generating electronic units to achieve a heat dissipating objective, and providing a stronger airflow by increasing the rotation speed of the fan is the easiest and most economical method. However, the aforesaid method has a problem of generating a loud noise.

Accordingly, the applicant of the present disclosure has devoted himself for improving the mentioned shortages.

### SUMMARY OF THE DISCLOSURE

The present disclosure is to provide a heat dissipation device having a noise cancelling module, in which with an installation of the noise cancelling module, the heat dissipating performance for the whole device is increased and a noise problem bothering the user is effectively improved.

Accordingly, the present disclosure provides a heat dissipation device having a noise cancelling module, which includes a seat body, a cover member, a fan, a heat dissipation fin set and a noise cancelling module. The cover member correspondingly covers the seat body. An accommodation chamber is formed between the seat body and the cover member. The cover member has an air inlet port and an air outlet port communicating both with the accommodation chamber. The fan is disposed in the accommodation chamber and arranged corresponding to the air inlet port. The fan has a plurality of blades. The heat dissipation fin set is disposed in the accommodation chamber and arranged corresponding to the air outlet port. The noise cancelling module generates a noise cancellation sound. The noise cancelling module is disposed on the cover member or the heat dissipation fin set to make the noise cancellation sound offset a noise generated when each of the blades rotates.

### BRIEF DESCRIPTION OF THE DRAWINGS

The features of the disclosure believed to be novel are set forth with particularity in the appended claims. The disclosure itself, however, may be best understood by reference to the following detailed description of the disclosure, which describes a number of exemplary embodiments of the disclosure, taken in conjunction with the accompanying drawings, in which:

FIG. 1 is a perspective view showing the assembly of a heat dissipation device having a noise cancelling module according to the present disclosure;

FIG. 2 is a front view showing the assembly of the heat dissipation device having the noise cancelling module according to the present disclosure;

FIG. 3 is a cross-sectional view showing the assembly of the heat dissipation device having the noise cancelling module according to the present disclosure;

FIG. 4 is a front view showing the assembly according to another embodiment of the present disclosure;

FIG. 5 is a cross-sectional view showing the assembly according to another embodiment of the present disclosure; and

FIG. 6 is a block diagram of the fan and the noise cancelling module according to the present disclosure.

### DETAILED DESCRIPTION OF THE DISCLOSURE

The technical contents of this disclosure will become apparent with the detailed description of embodiments accompanied with the illustration of related drawings as follows. It is intended that the embodiments and drawings disclosed herein are to be considered illustrative rather than restrictive.

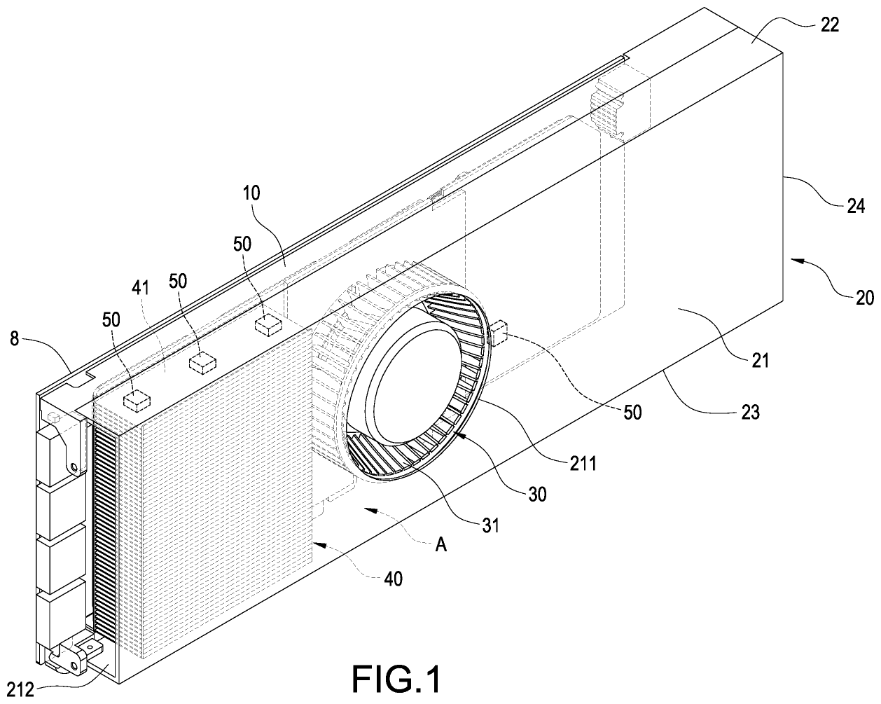

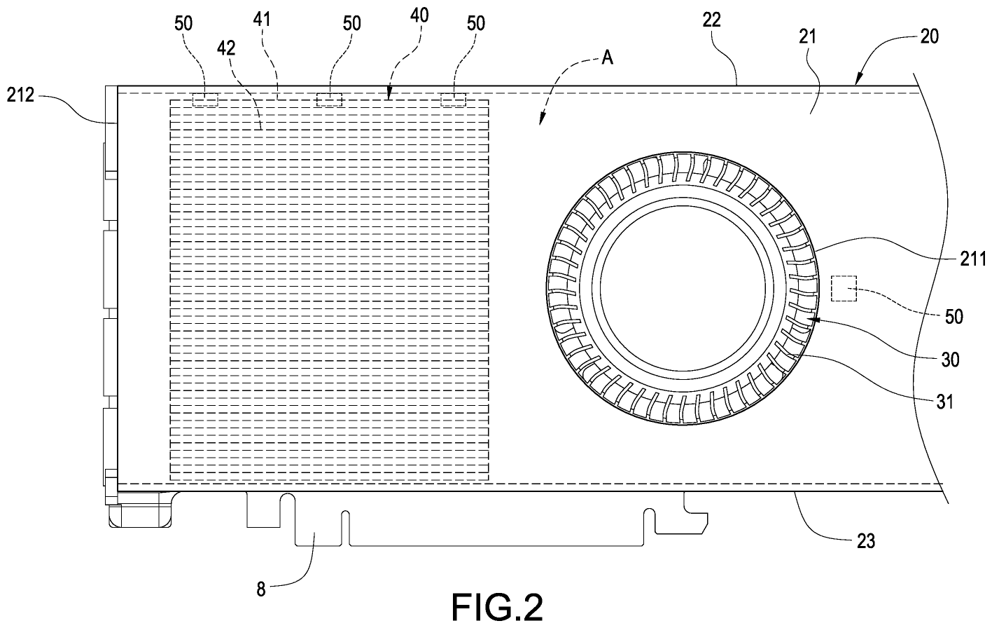

Please refer from FIG. 1 to FIG. 3, the present disclosure provides a heat dissipation device having a noise cancelling module, which may be applied on a graphics card 8 and mainly includes a seat body 10, a cover member 20, a fan 30, a heat dissipation fin set 40 and a noise cancelling module 50.

The seat body 10 is a rectangular frame, and composed of a plurality of side plates and a plurality of support rods being connected. A plurality of screw bolts are disposed at corresponding locations of each of the side plates, and locking units, for example screws, are used for locking and fastening.

The cover member 20 correspondingly covers on the seat member 10 and is disposed at one side of the seat body 10. An accommodation chamber A is formed between the seat body 10 and the cover member 20. The cover member 20 is made of a metal material and substantially formed in a rectangular shape. The cover member 20 mainly includes a surface plate 21, a top plate 22, a bottom plate 23 and a right plate 24 vertically extended from the surface plate 21. The top plate 22 and the bottom plate 23 are corresponding to each other in location. An air inlet port 211 communicating with the accommodation chamber A is formed at a central location of the surface plate 21. An air outlet port 212 is defined by the left side of the surface plate 21, the left side of the top plate 22 and the left side of the bottom plate 23.

The fan 30 is disposed in the accommodation chamber A and arranged corresponding to the air inlet port 211. The fan 30 has a plurality of blades 31. Each of the blades 31 is made of a metal material. A motor is used to drive each of the blades 31 of the fan 30 to rotate to make cooler air be blown into the accommodation chamber A via the air inlet port 211, and hotter air inside the accommodation chamber A is blown out via the air outlet port 212 to achieve a heat dissipating effect. According to the present disclosure, the fan 30 is operated according to a fan control signal. The greater value of the fan control signal, the higher of the rotation speed of the motor in the fan 30. As such, the heat dissipating effect is greater and a louder noise is generated. In some embodiments, the fan control signal is a square wave signal of a pulse width modulation (PWM), and the rotation speed of the motor in the fan 30 is adjusted through altering the duty cycle thereof. In some embodiments, the fan 30 may include one or a plurality of axial fans or centrifugal fans. The amounts of the fan 30, the fan type and the fan driving method are not intended to be limiting.

The noise generated by the fan 30 during operation is from an airflow generated by the motor during rotation. The narrow band portion of the noise may be from a thickness noise of a volume displacement generated when the blades 31 are operated, or a blade passing frequency (BPF) noise generated due to a variable loading force (including an axial lifting force and a pulling force of a blade surface) of a surface of the blade 31. Because the BPF and the relevant harmonic wave relative to a pressure disturbance generated when each of the blades 31 passes a fixed reference point, and a certain narrow band noise is generated when a tip end of the blade 31 generates a periodic pressure wave. On the other hand, when the airflow flows through the blade 31, the airflow shed at the boundary layer of the blade 31 or two sides of the blade tip to form an alternative vortex, and the phenomenon is defined as the vortex shedding. Instant speeds of the airflows at two sides of the blade 31 are different due to the vortex shedding, and the instant pressures at two sides of the blade 31 at different flow speeds are also different, thus the blade 31 generates vibrations and a certain wide band noise is generated.

The heat dissipation fin set 40 is disposed in the accommodation space A and arranged corresponding to the air outlet port 212. The heat dissipation fin set 40 includes a plurality of heat dissipation fins 41 spaced with intervals. An airflow channel 42 is formed between every two of the adjacent heat dissipation fins 41. The airflow channels 42 are in parallel with each other and correspondingly arranged relative to the airflow blown out via each of the blades 31 of the fan 30.

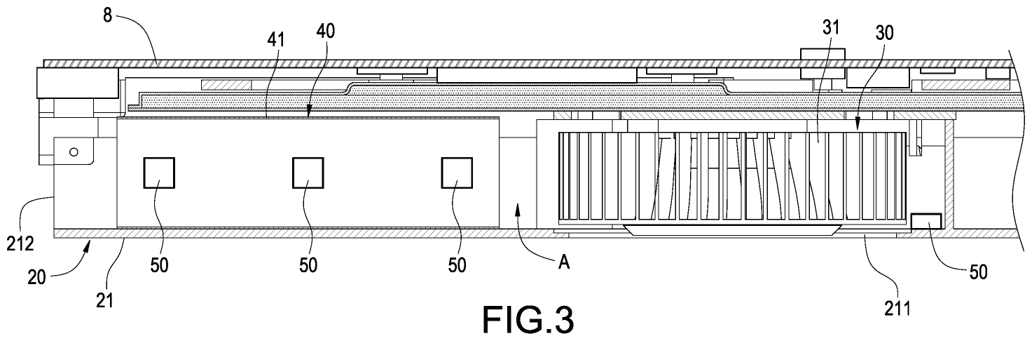

The noise cancelling module 50 is disposed on the cover member 20 or the heat dissipation fin set 40. When the noise cancelling module 50 is disposed on the cover member 20, the noise cancelling module 50 is located on an inner surface of the surface plate 21 and arranged to be close to the fan 30 as shown in FIG. 3. When the noise cancelling module 50 is disposed on the heat dissipation fin set 40, the noise cancelling module 50 may be located on an outer surface of the heat dissipation fin 41 arranged at the outmost side, and the noise cancelling module 50 may be arranged to be close to the fan 30 or a middle segment of the heat dissipation fin 41 or close to the air outlet port 212.

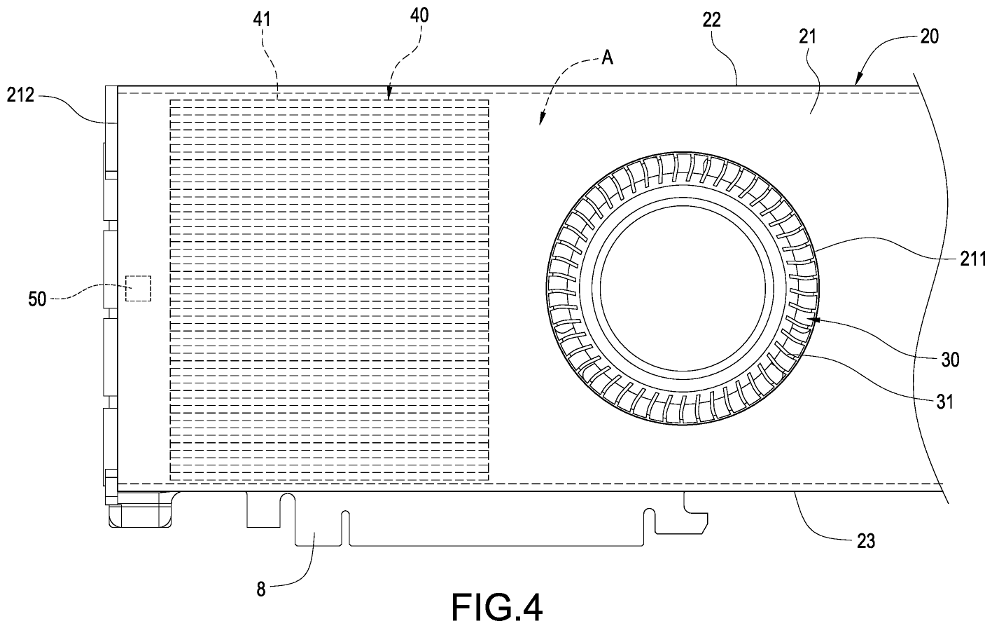

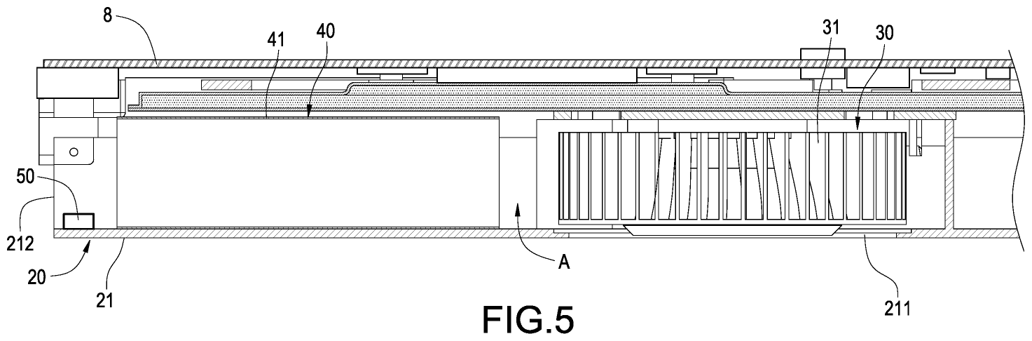

Please refer to FIG. 4 and FIG. 5, according to the heat dissipation device having the noise cancelling module provided by the present disclosure. In some embodiments, the noise cancelling module 50 may be located on the inner surface of the surface plate 21 and arranged to be close to the air outlet port 212, and the other structure is the same as the aforesaid arrangement.

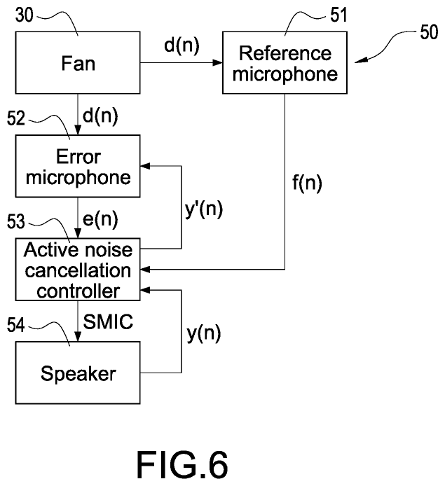

Please refer to FIG. 6, the noise cancelling module 50 mainly includes a reference microphone 51, an error microphone 52, an active noise cancellation (ANC) controller 53 and a speaker 54. Each of the aforesaid components is electrically connected via a circuit board or a conductive wire (not labeled in figures). The noise cancelling module 50 is electrically connected to the fan 30. If the noise cancelling module 50 is disposed at a location away from the fan 30, the noise cancelling module 50 is connected to the graphics card 8 or other peripheral electronic devices (not labeled in figures).

The reference microphone 51 is disposed at a location close to each of the blades 31 of the fan 30 and used to collect the noise generated when the fan 30 is operated. A measured wide band noise signal f(n) is transferred to the active noise cancellation controller 53. The wide band noise signal f(n) includes a wide band noise spectrum of the airflow noise generated when the fan 30 is operated. In some embodiments, the reference microphone 51 is a digital micro electro mechanical system (MEMS) microphone which is provided with performances of heat resisting, vibration resisting and high interference to radio frequency. However, the type of reference microphone 51 is not intended to be limiting.

The error microphone 52 is used to collect the whole noise generated when each of the blades 31 of the fan 30 is operated, and a corresponding error signal e(n) is outputted to the active noise cancellation controller 53. The error signal e(n) is defined as the noise signal desired to be eliminated when each of the blades 31 is operated. Because the fan is the main source of the noise, the error microphone 52 is disposed close to the fan 30. The distance between the reference microphone 51 and the active noise cancellation controller 53 is greater than that between the error microphone 52 and the active noise cancellation controller 53. The error microphone 52 detects the noise via a primary route and a secondary route. The primary route is defined as a signal transferring route between the fan 30 and the error microphone 52 to collect a noise signal d(n) via the primary route. The secondary route is defined as a signal transferring route between the speaker 54 and the error microphone 52 to collect a calibrated anti-phase noise signal y′(n) relevant to an anti-phase noise signal y(n) via the secondary route. Details are provided as follows. The error signal e(n) outputted by the error microphone 52 is a difference value between the noise signal d(n) and the calibrated anti-phase noise signal y′(n). When the value of the error signal e(n) is smaller, it represents that the noise cancellation effect is better. In some embodiments, the error microphone 52 is a digital micro MEMS microphone which is provided with performances of heat resisting, vibration resisting and high interference to radio frequency. The type of error microphone 52 is not intended to be limiting.

The active noise cancellation controller 53 receives a synchronous signal, receives the wide band noise signal f(n) from the reference microphone 51, and receives the error signal e(n) from the error microphone 52. The synchronous signal includes the structure of the fan 30 (for example the amount of blades of each fan) and an operation setting data (for example a rotation speed of the motor in different modes). With the synchronous signal and the wide band noise signal f(n), the active noise cancellation controller 53 calculates the wide band noise in the noise generated when the fan 30 is in an actual operating status. With the synchronous signal and the error signal e(n), the active noise cancellation controller 53 calculates the narrow band noise in the noise generated when the fan 30 is in an actual operating status. With the calculated wide band noise and the calculated narrow band noise, the active noise cancellation controller 53 provides a speaker control signal to drive the speaker 54, thus the anti-phase noise signal y(n) provided by the speaker 54 effectively offset the noise signal d(n), in other words the error signal e(n) is lowered to be close to zero, as close as possible.

The speaker 54 is an electronic unit capable of converting an electric signal into a sound signal. The speaker 54 often includes a diaphragm and a drive circuit composed of an electromagnetic iron and a sound coil. The speaker 54 is operated according to the speaker control signal provided by the active noise cancellation controller 53. When the current of the speaker control signal passes the sound coil, the sound coil vibrates with the frequency of the current, and the diaphragm connected to the sound coil also vibrates to push the ambient air to vibrate to generate a noise cancellation sound. In some embodiments, the diaphragm of the speaker 54 generates the anti-phase noise signal y(n) according to the speaker control signal.

While this disclosure has been described by means of specific embodiments, numerous modifications and variations could be made thereto by those skilled in the art without departing from the scope and spirit of this disclosure set forth in the claims.

What is claimed is:

1. A heat dissipation device, comprising:
a seat body;
a cover member, correspondingly covering the seat body to define an accommodation chamber therebetween, comprising an air inlet port and an air outlet port both communicating with the accommodation chamber;
a fan, disposed in the accommodation chamber and arranged corresponding to the air inlet port, and comprising a plurality of blades;
a heat dissipation fin set, disposed in the accommodation chamber and arranged corresponding to the air outlet port; and
a noise cancelling module, configured to generate a noise cancellation sound, disposed on the cover member or the heat dissipation fin set, and the noise cancellation sound offset a noise generated by each of the blades during rotation.

2. The heat dissipation device according to claim 1, wherein the noise cancelling module comprises a reference microphone, an error microphone, an active noise cancellation controller and a speaker electrically connected to one another.

3. The heat dissipation device according to claim 1, wherein the cover member comprises a surface plate, and the noise cancelling module is disposed on an inner surface of the surface plate and arranged adjacently to the air outlet port.

4. The heat dissipation device according to claim 1, wherein the cover member comprises a surface plate, and the noise cancelling module is disposed on an inner surface of the surface plate and arranged adjacently to the fan.

5. The heat dissipation device according to claim 1, wherein the heat dissipation fin set comprises a plurality of heat dissipation fins arranged spacedly, and the noise cancelling module is located on an outer surface of the heat dissipation fin arranged at an outmost side and is disposed adjacently to the fan.

6. The heat dissipation device according to claim 1, wherein the heat dissipation fin set comprises a plurality of heat dissipation fins arranged spacedly, and the noise cancelling module is located on an outer surface of the heat dissipation fin arranged at an outmost side and is disposed at a central location.

7. The heat dissipation device according to claim 1, wherein the heat dissipation fin set comprises a plurality of heat dissipation fins spaced with intervals, and the noise cancelling module is located on an outer surface of the heat dissipation fin arranged at an outmost side and disposed to be close to the air outlet port.

8. The heat dissipation device according to claim 1, wherein the noise cancelling module is electrically connected to the fan.

9. The heat dissipation device according to claim 1, wherein the noise cancelling module is electrically connected to an electronic device.

10. The heat dissipation device according to claim 1, wherein the heat dissipation fin set comprises a plurality of heat dissipation fins arranged spacedly, an airflow channel is defined between any two of the heat dissipation fins adjacent to each other, and a plurality of airflow channels are in parallel.
